(19) United States
(12) Patent Application Publication
(10) Pub. No.: US 2025/0151196 A1
(43) Pub. Date: May 8, 2025

(54) LOGIC BOARD HAVING SELECTABLE SECONDARY CONDUCTIVE TRACES

(71) Applicant: Hewlett-Packard Development Company, L.P., Spring, TX (US)

(72) Inventor: Marcus Joseph Benzel, Fort Collins, CO (US)

(73) Assignee: Hewlett-Packard Development Company, L.P., Spring, TX (US)

(21) Appl. No.: 18/837,431

(22) PCT Filed: Feb. 28, 2022
(86) PCT No.: PCT/US2022/018121

§ 371 Date: Aug. 9, 2024

(51) Int. Cl. H05K 1/11; H05K 3/40

(52) U.S. Cl. CPC H05K 1/116; H05K 3/4061; H05K 2201/09236; H05K 2201/09254; H05K 2203/1453

(57) ABSTRACT

A logic board includes topmost and bottommost layers, a primary trace layer, and first and second secondary trace layer respectively above and below the primary trace. The logic board includes a conductive via extending from the topmost or bottommost layer to the primary trace layer. The logic board includes a backdrilled hole concentric with the conductive via, from the bottommost layer at least to the second secondary trace layer and not reaching the primary trace layer, or from the topmost layer at least to the first secondary trace layer and not reaching the primary trace layer. The logic board includes a primary conductive trace within the primary trace layer and extending from the conductive via. The logic board includes first and second secondary conductive traces respectively within the first and second secondary trace layers and extending from the conductive via.

### BACKGROUND

Electronic devices, including computing devices such as computers, usually include logic boards, which may also be referred to as circuit boards. A logic board can have multiple electronic components mounted on the board. Examples of electronic components include integrated circuits (ICs), including processors such as central processing units (CPUs), as well as connectors such as M.2 connectors, and slots such as peripheral component interconnect express (PCIe) slots. Other example electronic components include discrete electrical devices, such as resistors, capacitors, and inductors. A logic board can have conductive traces printed or formed on its surfaces or within its constituent layers, as well as conductive vias to interconnect traces on different layers. The traces and vias conductively interconnect the electronic components mounted on the logic board.

### BRIEF DESCRIPTION OF THE DRAWINGS

FIGS. 1A, 1B, and 1C are cross-sectional top, front, and back view diagrams, respectively, of an example logic board having selectable secondary conductive traces.

FIGS. 2A and 2B are cross-sectional top and front view diagrams, respectively, of an example electronic device having a logic board in which a first selectable secondary conductive trace has been permanently enabled and a second selectable secondary conductive trace has been permanently disabled via a backdrilled hole.

FIGS. 3A and 3B are cross-sectional top and back view diagrams, respectively, of an example electronic device having a logic board in which a first selectable secondary conductive trace has been permanently disabled and a second selectable secondary conductive trace has been permanently enabled via a backdrilled hole.

FIG. 4 is a flowchart of an example method for fabricating a logic board having selectable secondary conductive traces and for permanently enabling one secondary conductive trace and permanently disabling another secondary conductive trace via a backdrilled hole.

### DETAILED DESCRIPTION

As noted in the background, a logic board for an electronic device can include conductive traces and conductive vias to conductively interconnect electronic components mounted on the board. A given type of logic board may be used in multiple different types of electronic devices, and modified to be used in each type of electronic device. For example, a type of logic board may be used in both a first type of electronic device in which a central processing unit (CPU) is connected to a peripheral component interconnect express (PCIe) slot and in a second type of electronic device in which the CPU is connected to an M.2 connector.

To select whether the CPU is connected to either the PCIe slot or to the M.2 connector on a given logic board, a multiplexer (“mux”) or a resistor network may be employed. The select line of a mux may be permanently or otherwise enabled or disabled to select either the PCIe slot when used in an electronic device of the first type, or the M.2 connector when used in an electronic device of the second type. Similarly, resistors in a resistor network may be permanently selectively enabled or disabled to select either the PCIe slot or the M.2 connector.

As communication speeds between the CPU and the PCIe slot or the M.2 connector have increased, usage of a resistor network has fallen from favor because resistor networks in general cannot accommodate faster communication speeds. While muxes can accommodate faster communication speeds, mux usage introduces signaling losses within the communication path between the CPU and the PCIe slot or the M.2 connector. Both resistor networks and muxes also take up space on logic boards, where such space is increasingly at a premium as logic boards become smaller and the number of electronic components mounted on them increases.

Techniques described herein ameliorate these issues. The techniques pertain to a logic board that provides for permanent enabling of one of a PCIe slot and an M.2 connector and permanent disabling of the other of the PCIe slot and the M.2 connector, for instance, without having to use either a resistor network or a mux. Rather, as will be described in detail, a backdrilled hole concentric with a conductive via is employed. Such techniques accommodate faster communication speeds between the CPU and the PCIe slot or the M.2 connector and further reduce signaling losses. Furthermore, these techniques take up less space on logic boards than techniques using resistor networks or muxes.

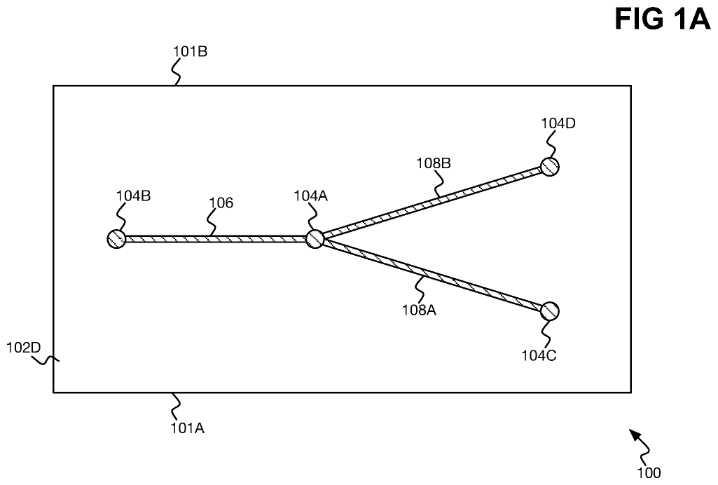

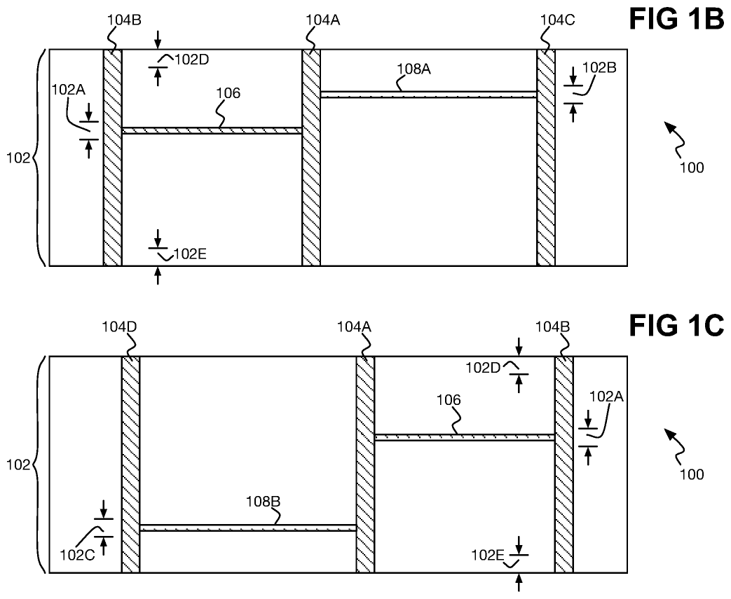

FIGS. 1A, 1B, and 1C show cross-sectional top, front, and back views, respectively, of an example logic board 100. Per the top view of FIG. 1A, the logic board 100 has a front side 101A and a back side 101B. The front view of FIG. 1B is thus from the front side 101A, whereas the back view of FIG. 1C is from the back side 101B.

The logic board 100 is made up of layers 102. The layers 102 include a primary trace layer 102A, a first secondary trace layer 102B above the primary trace layer 102A, and a second secondary trace layer 102C below the primary trace layer 102A. For example, the primary trace layer 102 may be the fifth layer of the logic board 100, and the secondary trace layers 102B and 102C may be the third and tenth layers, respectively. The layers 102 also include a topmost layer 102D at the top of the logic board 100 and a bottommost layer 102E at the bottom of the logic board 100.

The logic board 100 includes conductive vias 104A, 104B, 104C, and 104D that extend from the topmost layer 102D to the bottommost layer 102E of the logic board 100. The vias 104A, 104B, 104C, and 104D are conductive in that after formation the vias 104A, 104B, 104C, and 104D are filled with a conductive material. The conductive via 104B is for an electronic component, such as a CPU, mounted on the via 104B at the topmost layer 102D or the bottommost layer 102E of the logic board 100, or for a trace on the layer 102D or 102E extending from the via 104B to this electronic component.

The conductive via 104C is for an electronic component, such as a PCIe slot, mounted on the via 104C at the topmost layer 102D or the bottommost layer 102E, or for a trace on the layer 102D or 102E extending from the via 104C to to this electronic component. The conductive via 104D is for an electronic component, such as an M.2 connector, mounted on the via 104D at the topmost layer 102D or the bottommost layer 102E, or for a trace on the layer 102D or 102E extending from the via 104D to this electronic component.

The conductive via 104A is backdrilled from the topmost layer 102D at least through the secondary trace layer 102B and not reaching the primary trace layer 102A to select the electronic component corresponding to the via 104D. The conductive via 104A is backdrilled from the bottommost layer 102E at least through the secondary trace layer 102C and not reaching the primary trace layer 102A to select the electronic component corresponding to the via 104C.

The logic board 100 includes a primary conductive trace 106 within the primary trace layer 102A and extending from the conductive via 104A to the conductive via 104B. The primary conductive trace 106 within the primary trace layer 102A is for the electronic component corresponding to the conductive via 104B. If the primary trace layer 102B is the fifth layer, and the corresponding electronic component is a CPU, the primary conductive trace 106 may be considered a CPU fifth layer trace.

The logic board 100 includes a first selectable secondary conductive trace 108A within the secondary trace layer 102B and extending from the conductive via 104A to the conductive via 104C. The secondary conductive trace 108A is for the electronic component corresponding to the via 104C. If the secondary trace layer 102B is the third layer, and the corresponding electronic component is a PCIe slot, the secondary conductive trace 108A may be considered a PCIe slot third layer trace. The secondary conductive trace 108A is selectable in that the trace 108A can be selected by backdrilling the via 104A from the bottommost layer 102E at least through the secondary trace layer 102C and not reaching the primary trace layer 102A.

The logic board 100 includes a second selectable secondary conductive trace 108B within the secondary trace layer 102C and extending from the conductive via 104A to the conductive via 104D. The secondary conductive trace 108B is for the electronic component corresponding to the via 104D. If the secondary trace layer 102C is the tenth layer, and the corresponding electronic components is an M.2 connector, the secondary conductive trace 108B may be considered an M.2 connector tenth layer trace. The secondary conductive trace 108B is selectable in that the trace 108B can be selected by backdrilling the via 104B from the topmost layer 102D at least through the secondary trace layer 102B and not reaching the primary trace layer 102A.

The logic board 100 as shown in FIGS. 1A, 1B, and 1C is in a state in which both the selectable secondary conductive traces 108A and 108B are conductively connected to the primary conductive trace 106, via the conductive via 104A. The logic board 100 may in a first case be used in an electronic device in which the electronic component corresponding to the via 104B is to be conductively connected to the electronic component corresponding to the via 104C (and not to the electronic component corresponding to the via 104D). The logic board 100 may in a second case be used in an electronic device in which the electronic component corresponding to the via 104B is to be conductively connected to the electronic component corresponding to the via 104D (and not to the electronic component corresponding to the via 104C).

In the first case, the via 104A is backdrilled from the bottommost layer 102E through the secondary trace layer 102C to conductively disconnect the secondary conductive trace 108B from the primary conductive trace 106. As a result, the via 104D and the electronic component corresponding to the via 104D are conductively disconnected from the via 104B and the electronic component corresponding to the via 104B. Backdrilling of the via 104A does not reach the primary trace layer 102A, however, so as not to conductively disconnect the primary conductive trace 106 from the via 104A.

In the second case, the via 104A is backdrilled from the topmost layer 102D through the secondary trace layer 102B to conductively disconnected the secondary conductive trace 108A from the primary conductive trace 106. As a result, the via 104C and the electronic component corresponding to the via 104C are conductively disconnected from the via 104B and the electronic component corresponding to the via 104B. Backdrilling of the via 104A does not reach the primary trace layer 102A, however, so as not to conductively disconnect the primary conductive trace 106 from the via 104A.

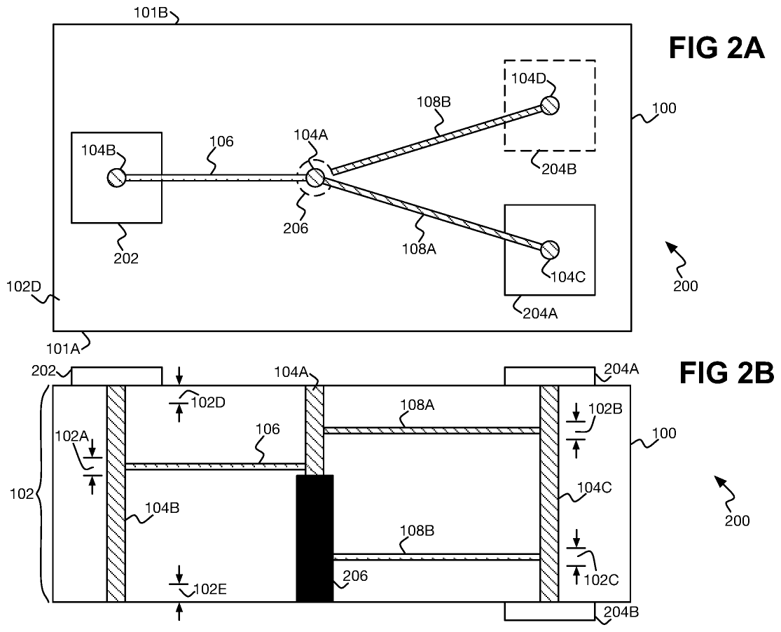

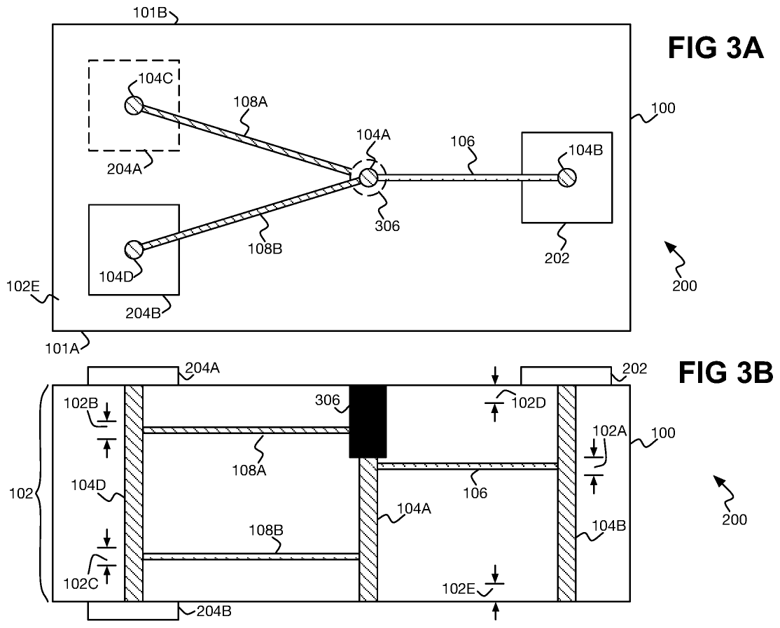

FIGS. 2A and 2B show cross-sectional top and front views, respectively, of an electronic device 200 including the logic board 100 in the first case, and FIGS. 3A and 3B show cross-sectional top and back views, respectively, of the electronic device 200 including the logic board 100 in the second case. The electronic device 200 includes an electronic component 202, such as a CPU, mounted on the conductive via 104B at the topmost layer 102D. The component 202 may instead be mounted at the bottommost layer 102E, and instead of being mounted on the via 104B, may be mounted to a trace on the layer 102D or 102E that extends to the via 104B.

The electronic device 200 includes an electronic component 204A, such as a PCI slot, mounted on the conductive via 104C at the topmost layer 102D. The component 204A may instead be mounted at the bottommost layer 102E, and instead of being mounted on the via 104C, may be mounted to a trace on the layer 102D or 102E that extends to the via 104C. The electronic device 200 includes an electronic component 204B, such as an M.2 connector, mounted on the conductive via 104D at the bottom most layer 102E. The component 204B may instead be mounted at the topmost layer 102D, and instead of being mounted on the via 104D, may be mounted on a trace on the layer 102E or 102D that extends to the via 104D.

In the first case of FIGS. 2A and 2B, a backdrilled hole 206 concentric with and having a diameter at least as large as that of the conductive via 104A extends from the layer 102E at the bottom of the logic board 100, at least through the secondary trace layer 102C, but not reaching the primary trace layer 102A. The backdrilled hole 206 permanently selectively enables conductive connection of the primary conductive trace 106 to the secondary conductive trace 108A, and permanently selectively disables conduction connection of the primary conductive trace 106 to the secondary conductive trace 108B. Therefore, the electronic component 202 is conductively connected to the electronic component 204A and conductively disconnected from the electronic component 204B.

In the second case of FIGS. 3A and 3B, a backdrilled hole 306 concentric with and having a diameter at least as large as that of the conductive via 104A extends from the layer 102D at the top of the logic board 100, at least through the secondary trace layer 102B, but not reaching the primary trace layer 102A. The backdrilled hole 306 permanently selectively enables conductive connection of the primary conductive trace 106 to the secondary conductive trace 108B, and permanently selectively disables conductive connection of the primary conductive trace 106 to the secondary conductive trace 108A. Therefore, the electronic component 202 is conductive connected to the electronic component 204B and conductively disconnected from the electronic component 204A.

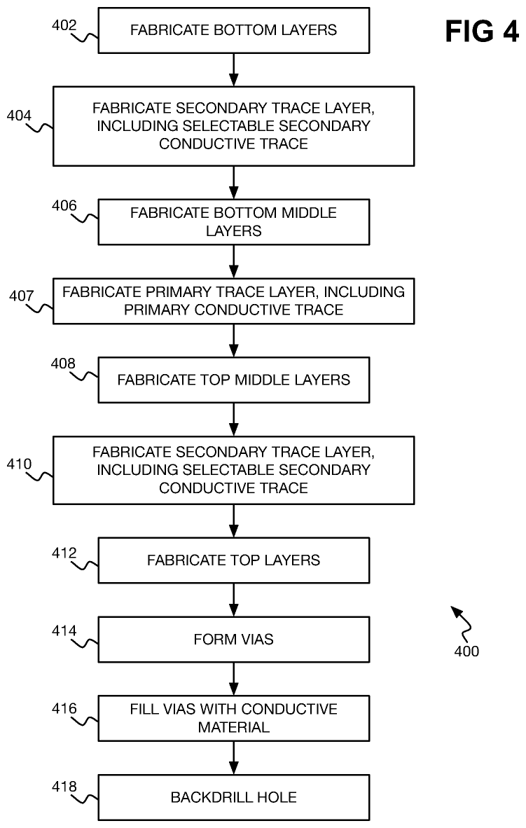

FIG. 4 shows an example method 400 for fabricating the logic board 100. The method 400 includes fabricating the bottom layers 102 of the logic board 100, from the bottommost layer 102E through the layer 102 below the secondary trace layer 102C (402). The method 400 includes fabricating the secondary trace layer 102C, including the selectable secondary conductive trace 108B within the secondary trace layer 102C (404). The method 400 includes fabricating bottom middle layers 102, from the layer 102 above the secondary trace layer 102C to the layer 102 below the primary trace layer 102A (406).

The method 400 includes fabricating the primary trace layer 102A, including the primary conductive trace 106 within the primary trace layer 102A (407). The method 400 includes fabricating top middle layers 102, from the layer 102 above the primary trace layer 102A to the layer 102 below the secondary trace layer 102B (408). The method 400 includes fabricating the secondary trace layer 102B, including the selectable secondary conductive trace 108A within the secondary trace layer 102B (410). The method 400 includes fabricating the top layers 102 of the logic board 100, from the layer 102 above the secondary trace layer 102B to the topmost layer 102D (412).

The method 400 includes forming the vias 104A, 104B, 104C, and 104D within the logic board (414), followed by filing the vias 104A, 104B, 104C, and 104D with conductive material (416) to render them conductive. When the resultantly fabricated logic board 100 is to be used in a particular type of electronic device, the method 400 includes then concentrically backdrilling the hole 206 or 306 through the conductive via 104A (418). If the secondary conductive trace 108A is to be selected, the hole 206 is backdrilled from the bottommost layer 102E. If the secondary conductive trace 108B is to be selected, the hole 306 is backdrilled from the topmost layer 102D.

The techniques described herein thus provide for a logic board 100 that can be used in different types of devices that may conductively connect a CPU (or other electronic component) to a PCIe slot (or other electronic component) or to an M.2 connector (or other electronic component). Such selective conductive connection is achieved without the usage of a resistor network or a mux. Rather, a hole 206 or 306 is concentrically backdrilled through a via 104A from which the primary conductive trace 106 corresponding to the CPU and the secondary conductive traces 108A and 108B respectively corresponding to the PCIe slot and the M.2 connector extend.

We claim:

1. A logic board comprising:
a plurality of layers, including topmost and bottommost layers, a primary trace layer, and first and second secondary trace layers respectively above and below the primary trace layer;
a conductive via extending from the topmost layer to the bottommost layer;
a primary conductive trace within the primary trace layer and extending from the conductive via; and
first and second selectable secondary conductive traces respectively within the first and second selectable secondary trace layers and extending from the conductive via.

2. The logic board of claim 1, further comprising:
a backdrilled hole at least as large as and concentric with the conductive via, from the topmost layer at least to the first selectable secondary trace layer and not reaching the primary trace layer, resulting in permanent selective enabling of the second selectable secondary conductive trace with respect to conductive connection to the primary conductive trace via the conductive via and permanent selective disabling of the first selectable secondary conductive trace with respect to conductive connection to the primary conductive trace via the backdrilled hole.

3. The logic board of claim 1, further comprising:
a backdrilled hole at least as large as and concentric with the conductive via, from the bottommost layer at least to the second selectable trace layer and not reaching the primary trace layer, resulting in permanent selective enabling of the first selectable secondary conductive trace with respect to conductive connection to the primary conductive trace via the conductive via and permanent selective disabling of the second selectable secondary conductive trace with respect to conductive connection to the primary conductive trace via the backdrilled hole.

4. The logic board of claim 1, wherein the conductive via is a first conductive via, and the logic board further comprises:
a second conductive via extending from the topmost and/or bottommost layer to the primary trace layer, the primary conductive trace extending from the first conductive via to the second conductive via.

5. The logic board of claim 4, further comprising:
a third conductive via extending from the topmost and/or bottommost layer to the to the first selectable secondary trace layer, the first selectable secondary conductive trace extending from the first conductive via to the third conductive via; and
a fourth conductive via extending from the topmost and/or bottommost layer to the to the second selectable secondary trace layer, the second selectable secondary conductive trace extending from the first conductive via to the fourth conductive via.

6. An electronic device comprising:
a logic board comprising:
a plurality of layers, including topmost and bottommost layers, a primary trace layer, and first and second secondary trace layers respectively above and below the primary trace layer;
a conductive via extending from the topmost or bottommost layer to the primary trace layer;
a backdrilled hole at least as large as and concentric with the conductive via, from the bottommost layer at least to the second secondary trace layer and not reaching the primary trace layer, or from the topmost layer at least to the first secondary trace layer and not reaching the primary trace layer;
a primary conductive trace within the primary trace layer and extending from the conductive via; and
first and second secondary conductive traces respectively within the first and second secondary trace layers and extending from the conductive via.

7. The electronic device of claim 6, wherein the conductive via extends from the topmost layer to the primary trace layer and the backdrilled hole extends from the bottommost layer at least to the second secondary trace layer and not reaching the primary trace layer,
wherein the first secondary conductive trace is permanently conductively connected to the primary conductive trace via the conductive via, and the second secondary conductive trace is permanently conductively disconnected from the primary conductive trace via the backdrilled hole.

8. The electronic device of claim 7, wherein the conductive via is a first conductive via, and the logic board further comprises:
a second conductive via extending from the topmost and/or bottommost layer to the first secondary trace layer, the first secondary conductive trace extending from the first conductive via to the second conductive via,
and wherein the electronic device further comprises an electronic component mounted to a top or bottom of the logic board and conductively connected to the second conductive via.

9. The electronic device of claim 6, wherein the conductive via extends from the bottommost layer to the primary trace layer and the backdrilled hole extends from the topmost layer at least to the first secondary trace layer and not reaching the primary trace layer,
wherein the second secondary conductive trace is permanently conductively connected to the primary conductive trace via the conductive via, and the first secondary conductive trace is permanently conductively disconnected from the primary conductive trace via the backdrilled hole.

10. The electronic device of claim 9, wherein the conductive via is a first conductive via, and the logic board further comprises:
a second conductive via extending from the topmost and/or bottommost layer to the second secondary trace layer, the second secondary conductive trace extending from the first conductive via to the second conductive via,
and wherein the electronic device further comprises an electronic component mounted to a top or bottom of the logic board and conductively connected to the second conductive via.

11. The electronic device of claim 6, wherein the conductive via is a first conductive via, and the logic board further comprises:
a second conductive via extending from the topmost and/or bottommost layer to the primary trace layer, the primary conductive trace extending from the first conductive via to the second conductive via,
and wherein the electronic device further comprises an electronic component mounted to a top or bottom of the logic board and conductively connected to the second conductive via.

12. A method comprising:
fabricating one or multiple bottom layers of a logic board;
fabricating a second selectable secondary trace layer of the logic board on the bottom layers, including a second selectable secondary conductive trace within the second selectable secondary trace layer;
fabricating one or multiple bottom middle layers of the logic board on the second selectable secondary trace layer;
fabricating a primary trace layer of the logic board on the bottom middle layers, including a primary conductive trace within the primary trace layer;
fabricating one or multiple top middle layers of the logic board on the primary trace layer;
fabricating a first selectable secondary trace layer of the logic board on the top middle layers, including a first selectable secondary conductive trace within the first selectable secondary trace layer;
fabricating one or multiple top layers of the logic board on the first selectable secondary trace layer;
forming a via from a topmost layer of the logic board to a bottommost layer of the logic board, the primary trace layer and the first and second selectable secondary conductive traces extending from the via; and
filling the via with a conductive material.

13. The method of claim 12, further comprising:
backdrilling a hole at least as large as and concentric with the via, from the topmost layer at least to the first selectable secondary trace layer and not reaching the primary trace layer, resulting in permanent selective enabling of the second selectable secondary conductive trace with respect to conductive connection to the primary conductive trace via the via and permanent selective disabling of the first selectable secondary conductive trace with respect to conductive connection to the primary conductive trace via the backdrilled hole.

14. The method of claim 12, further comprising:
backdrilling a hole at least as large as and concentric with the via, from the bottommost layer at least to the second selectable secondary trace layer and not reaching the primary trace layer, resulting in permanent selective enabling of the first selectable secondary conductive trace with respect to conductive connection to the primary conductive trace via the via and permanent selective disabling of the second selectable secondary conductive trace with respect to conductive connection to the primary conductive trace via the backdrilled hole.

15. The method of claim 12, wherein the via is a first via, and the method further comprises:
forming a second via from the topmost layer and/or the bottommost layer to the primary trace layer, the primary conductive trace extending from the first via to the second via; and
filling the second via with a conductive material.
